(19) United States
(12) Patent Application Publication
(10) Pub. No.: US 2025/0165383 A1
(43) Pub. Date: May 22, 2025

(54) APPARATUSES, SYSTEMS, AND METHODS FOR DECODING METADATA POSITION DURING READ OPERATIONS

(71) Applicant: Micron Technology, Inc., Boise, ID (US)

(72) Inventor: Sujeet Ayyapureddi, Boise, ID (US)

(73) Assignee: Micron Technology, Inc., Boise, ID (US)

(21) Appl. No.: 18/920,337

(22) Filed: Oct. 18, 2024

Related U.S. Application Data
(60) Provisional application No. 63/600,132, filed on Nov. 17, 2023.

(51) Int. Cl. G06F 12/02

(52) U.S. Cl. CPC G06F 12/0223

(57) ABSTRACT

A memory device stored data and associated metadata. During a read operation, memory receives a column address and decodes it into a column select value. Based on a range of values which contain that column select value, a block of metadata which includes the associated metadata is read. The memory subtracts a minimum value of the range of values from the column select value to determine a metadata location value. The metadata location value indicates a relative position of the associated metadata within the block of metadata, and the data and associated metadata are read out.

### CROSS-REFERENCE TO RELATED APPLICATIONS

This application claims the filing benefit of U.S. Provisional Application No. 63/600,132, filed Nov. 17, 2023. This application is incorporated by reference herein in its entirety and for all purposes.

### BACKGROUND

This disclosure relates generally to semiconductor devices, and more specifically to semiconductor memory devices. In particular, the disclosure relates to volatile memory, such as dynamic random access memory (DRAM). Information may be stored on individual memory cells of the memory as a physical signal (e.g., a charge on a capacitive element). During an access operation, an access command may be received along with address information which specifies which memory cells should be accessed.

There is a growing interest in enabling the memory to store additional information in the array which is associated with pieces of data. For example, error correction information and/or metadata may be stored in the array along with their associated data. During read operations, a large block of data may be read which includes the metadata associated with several different data addresses. There may be a need to rapidly and easily locate the metadata associated with the current read address within that block.

### BRIEF DESCRIPTION OF THE DRAWINGS

FIG. 1 is a block diagram of a semiconductor device according to an embodiment of the disclosure.

FIG. 2 is a block diagram of access circuits according to some embodiments of the present disclosure.

FIG. 3 is a block diagram of a memory device according to some embodiments of the present disclosure.

FIG. 4 is a block diagram of a metadata location decoder circuit according to some embodiments of the present disclosure.

FIG. 5 is a flow chart of a method according to some embodiments of the present disclosure.

### DETAILED DESCRIPTION

The following description of certain embodiments is merely exemplary in nature and is in no way intended to limit the scope of the disclosure or its applications or uses. In the following detailed description of embodiments of the present systems and methods, reference is made to the accompanying drawings which form a part hereof, and which are shown by way of illustration specific embodiments in which the described systems and methods may be practiced. These embodiments are described in sufficient detail to enable those skilled in the art to practice presently disclosed systems and methods, and it is to be understood that other embodiments may be utilized, and that structural and logical changes may be made without departing from the spirit and scope of the disclosure. Moreover, for the purpose of clarity, detailed descriptions of certain features will not be discussed when they would be apparent to those with skill in the art so as not to obscure the description of embodiments of the disclosure. The following detailed description is therefore not to be taken in a limiting sense, and the scope of the disclosure is defined only by the appended claims.

Memory arrays may generally include a number of memory cells arranged at the intersection of word lines (rows) and bit lines/digit lines (columns). The columns may be grouped together into column planes, and a column select (CS) signal may be used to select a set of columns within each of the active column planes to provide data. When an access command is received, the memory may prefetch a codeword (e.g., a number of bits of data) along with one or more associated bits from the memory and either replace the prefetched data with new data (e.g., as part of a write operation) or provide the prefetched data off the memory device (e.g., as part of a read operation).

Memory devices may store additional information which is associated with each codeword. For example, the additional information may include parity bits which are used as part of an error correction scheme, metadata which includes information about the data codeword (or is a portion of information about a larger set of data which includes the codeword), or combinations thereof. During an example read operation, the memory may first prefetch a block of metadata and store it. This block of metadata may include the metadata associated with a number of different data codewords. For example, if the data prefetch is 256 bits, and there are 16 bits of metadata for every 256 bits of data, then the prefetched block of metadata may include 256 bits of metadata or 16 sets of 16 bits of metadata, each associated with a different data codeword. When the data is read, the memory may use the column address associated with the data to locate the metadata associated with that data within the stored block of metadata so the data and metadata can be provided together. There may be a need to perform this operation quickly and without requiring extensive circuitry.

The present disclosure is drawn to apparatuses, systems, and methods for decoding metadata position during read operations. During a read operation the memory receives a column address and decodes it into a CS signal. That CS signal falls within a range of CS values, and that range is associated with a block of metadata. The block of metadata associated with that range is read out of the array and saved in a plurality of metadata latches. A metadata location decoder circuit subtracts a minimum value of the range of CS values from the CS signal to generate a metadata location. Based on the metadata location, a set of metadata from the block is read from the latches and provided, along with the data. In this manner, the metadata location decoder circuit determines a relative position of the CS value within the range of CS values and uses that relative position to locate the relevant metadata set within the metadata block. This may be useful as subtraction may be a quick and easy to implement manner of locating the relevant metadata within the block.

For example, the memory may receive a read command and column address which is decoded into CS1. The CS value (CS1) falls within a first range of CS values from CS0 to CS15. The memory reads and stores the block of metadata associated with CS0-CS15 into sixteen sets of latches, each of which stores a set of metadata. The metadata location decoder subtracts the minimum value from the range (0) from the current value (1) to get a value of 1. Accordingly, the metadata location decoder indicates that the set of metadata in the set of latches with the index of ‘1’ is the set associated with the data read responsive to CS1. In another example operation, the column address may be decoded into CS17. That CS value falls within a second range (CS16-CS31) and so a different block of metadata is read and stored in the metadata latches. The metadata location decoder subtracts the minimum value of the range (16) from the value (17) and gets one. Accordingly, the metadata is still stored in the set of latches with the index of ‘1’ although the metadata will be different since a different block of metadata (associated with a different range of CS values) was read.

It may be especially useful to locate the metadata in this manner in a memory that performs consecutive accesses to different CS values within a CS range. For example, in a low power memory such as an LPDDR5 memory, in order to save power the memory may activate a row, and then perform multiple successive read operations along different CS values on that row. If the CS values are accessed sequentially (or close to) then the same block of metadata may remain stored in the metadata latches and the metadata location circuit will only need to identify the set of latches which store the metadata associated with the current read operation.

As used herein, the term data may represent any bits of information that the controller wishes to store and/or retrieve from the memory. The term metadata may represent any bits of information about the data which the controller writes to and/or receives from the memory. For example, the metadata may be information that the controller generates about the data, about how or where the data memory is stored in the memory, about how many errors have been detected in the data, etc. The data and the metadata together represent information written to the memory by a controller and then also read from the memory by the controller, with the data and metadata differing in content and how they are generated in that the metadata is based on information about the data. The term parity may represent any bits generated by an error correction circuit of the memory based on the data, metadata, or combinations thereof. The parity may generally stay within the memory. In some embodiments, the amount of data and/or metadata retrieved as part of a single access operation may represent a set of bits which are a fragment of a larger piece of information. For example, the metadata bits retrieved as part of a single access operation (e.g., 4 bits) may not have any meaning on their own but may have meaning when combined with sets of metadata bits retrieved as part of other access operations (e.g., to other memory arrays and/or to the same array at different times).

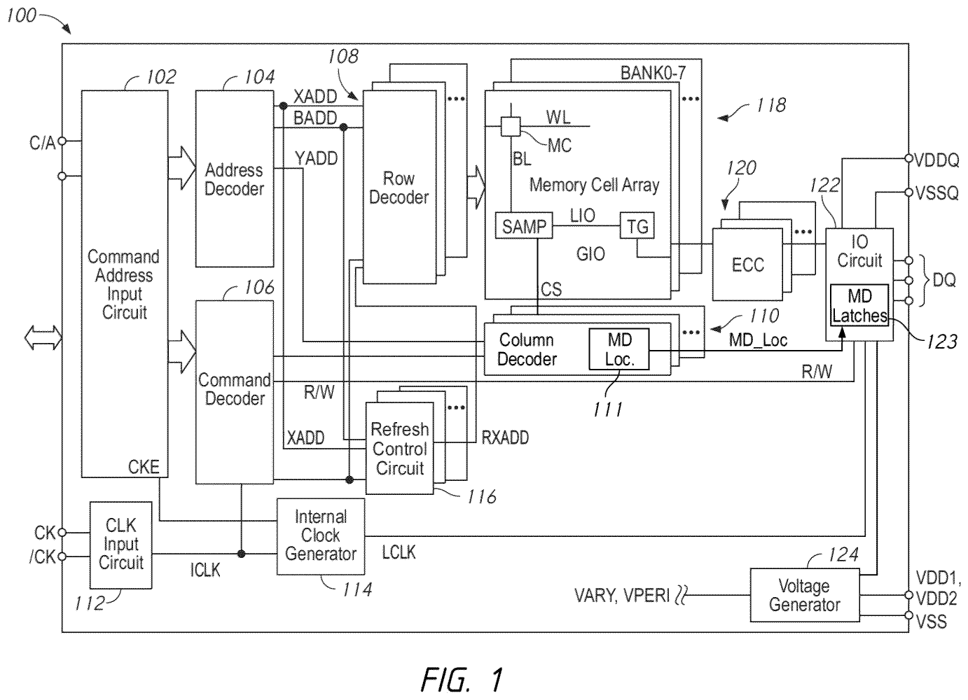

FIG. 1 is a block diagram of a semiconductor device according to an embodiment of the disclosure. The semiconductor device 100 may be a semiconductor memory device, such as a DRAM device integrated on a single semiconductor chip. The device may be operated by a host, or controller, such as a processor. In some embodiments, the memory and its controller may be separate components. In some embodiments, the memory and controller may be integrated together, for example into a system on a chip.

The semiconductor device 100 includes a memory array 118. The memory array 118 is shown as including a plurality of memory banks. In the embodiment of FIG. 1, the memory array 118 is shown as including eight memory banks BANK0-BANK7. More or fewer banks may be included in the memory array 118 of other embodiments. For example, there may be 4, 16, 32, or other numbers of banks. In some embodiments, multiple banks (and their affiliated circuits) may be operated together, as described in more detail herein.

Each memory bank includes a plurality of word lines WL, a plurality of bit lines BL, and a plurality of memory cells MC arranged at intersections of the plurality of word lines WL and the plurality of bit lines BL. The selection of the word line WL is performed by a row decoder 108 based on a row address XADD and the selection of the bit lines BL is performed by a column decoder 110 based on a column address YADD. In the embodiment of FIG. 1, the row decoder 108 includes a respective row decoder for each memory bank and the column decoder 110 includes a respective column decoder for each memory bank.

The bit lines BL are coupled to a respective sense amplifier (SAMP). During an example read operation, a word line is activated and data from that memory cell is coupled to the intersecting the bit line BL where it is amplified by the sense amplifier SAMP and transferred to an ECC circuit 120 over local data lines (LIO), transfer gate (TG), and global data lines (GIO). Conversely, write data outputted from the ECC circuit 120 is transferred to the bit line BL over the complementary main data lines GIO, the transfer gate TG, and the complementary local data lines LIO, amplified by the sense amplifier and written to the memory cell MC coupled to the bit line BL at the intersection with an active word line WL.

The semiconductor device 100 may employ a plurality of external terminals, such as solder pads, that include command and address (C/A) terminals coupled to a command and address bus to receive commands and addresses, clock terminals to receive clocks CK and /CK, data terminals DQ coupled to a data bus to provide data, and power supply terminals to receive power supply potentials VDD, VSS, VDDQ, and VSSQ.

The clock terminals are supplied with external clocks CK and/CK that are provided to an input circuit 112. The external clocks may be complementary. The input circuit 112 generates an internal clock ICLK based on the CK and/CK clocks. The ICLK clock is provided to the command decoder 106 and to an internal clock generator 114. The internal clock generator 114 provides various internal clocks LCLK based on the ICLK clock. The LCLK clocks may be used for timing operation of various internal circuits. The internal data clocks LCLK are provided to the input/output circuit 122 to time operation of circuits included in the input/output circuit 122, for example, to data receivers to time the receipt of write data. The input/output circuit 122 may include a number of interface connections, each of which may be couplable to one of the DQ pads (e.g., the solder pads which may act as external connections to the device 100).

The C/A terminals may be supplied with memory addresses as part of access operations. The memory addresses supplied to the C/A terminals are transferred, via a command/address input circuit 102, to an address decoder 104. The address decoder 104 receives the address and supplies a decoded row address XADD to the row decoder 108 and supplies a decoded column address YADD to the column decoder 110. The row address XADD may be used to determine which row should be opened (e.g., which word line should be activated), which may cause the data in the memory cells along that word line to be coupled to the intersecting bit lines. The column decoder 110 may provide one or more column select signals CS based on the column address, which may be used to determine which bit lines are coupled to the LIO. The address decoder 104 may also supply a decoded bank address BADD, which may indicate the bank or banks of the memory array 118 where the access operation should be performed.

The C/A terminals may be supplied with commands. Examples of commands include timing commands for controlling the timing of various operations, access commands for accessing the memory, such as read commands for performing read operations and write commands for performing write operations, as well as other commands and operations. The access commands may be associated with one or more row address XADD, column address YADD, and bank address BADD to indicate the memory cell(s) to be accessed.

The commands may be provided as internal command signals to a command decoder 106 via the command/address input circuit 102. The command decoder 106 includes circuits to decode the internal command signals to generate various internal signals and commands for performing operations. For example, the command decoder 106 may provide signals which indicate if data is to be read, written, etc.

The memory device 100 may store different types of information in the array 118. For example, a controller may read and write data to the array. That data may have associated metadata (which for example may indicate one or more pieces of information about the data) which is also written by and read out to the controller. The memory device 100 includes an error correction code (ECC) circuit 120 which generates parity bits based on the data and/or metadata when they are written. When the data and/or metadata is read, along with its associated parity, the ECC circuit 120 uses the associated parity to locate errors in the data and/or parity.

When metadata is enabled, the memory device 100 may use a two-pass access system to retrieve the data and metadata together. The device 100 accesses a block of metadata in a first pass, stores the block of metadata in metadata latches 123 (which are shown in FIG. 1 as a component of the IO circuit 122), and then accesses the data in a second pass. In some embodiments, for consistency in the memory architecture, the block of metadata may be the same size (e.g., a same number of bits) as the amount of data read during an access operation. However, since data and metadata are generally not matched at a 1:1 ratio, the block of metadata may include metadata for many different column addresses worth of data. Accordingly, a metadata location decoder circuit 111 (which is shown in FIG. 1 as a component of the column decoder 110) is used to determine which portion of the block of metadata is the metadata associated with the data.

During read operations column decoder 110 may decode the column address YADD into a value of the column select signal associated with the bit lines where the data is stored. Based on that CS value, the column decoder 110 also generates a value of the CS signal associated with where the MD is stored the value of CS where the metadata is stored may be based on a range of CS values which includes the CS value where the data is located. For example, a first range may be associated with a first CS value for metadata, a second range may be associated with a second CS value for metadata and so forth. If the CS value for metadata is different than the previous access operation, the CS value for the metadata is provided by the column decoder 110 and the metadata is read out and stored in the metadata latches 123 and then the CS value for the data is provided by the column decoder and the data is read out. If the CS value for metadata is the same as the previous access operation, then only the CS value for data is provided and only the data is read out. When the data is read out, the metadata location decoder circuit determines a relative position of the data CS value within the range of CS values and generates a relative position signal or metadata location signal MD_Loc, which is used to determine which of the metadata latches 123 store the metadata associated with that data.

For example, when a read command is received (as well as row, column, and bank addresses), the row decoder 108 activates a word line based on the row address XADD. The column decoder decodes the column address YADD into a data CS value. The column decoder 110 generates a metadata CS value based on the data CS value (e.g., a range that the data CS value falls in), and if the value of the metadata CS value is different than a previous metadata CS value, provides the metadata CS value to the array 118. Responsive to the metadata CS value, a block of metadata may be read out to the ECC circuit 120 along with its associated parity and any errors may be detected/corrected. The corrected metadata block is stored in metadata latches 123. The column decoder 110 then provides the data CS signal, and the data may be read out along with its associated parity and the ECC circuit 120 may detect/correct errors in the data. The metadata location decoder 111 determines which portion of the block of metadata stored in the metadata latches 123 is associated with the data and provides the metadata relative position signal MD_Loc to the metadata latches. The corrected data and the portion of the stored block of metadata associated with MD_Loc is provided to the DQ terminals.

During an example write operation, the memory device 100 receives a write command and data (or metadata) to be written (as well as row, column, and bank addresses). The ECC circuit 120 generates parity bits based on the data (or metadata). The row decoder activates a word line based on the row address XADD. The column decoder decodes the column address YADD into a CS value. The data (or metadata) and parity is written along the bit lines selected by the CS value to the memory cells at the intersection with the active word line.

In some memory implementations, such as low power memories (e.g., LPDDR) access operations may generally be performed on a number of consecutive CS values (for the data) along a single row. For example, a sequence of reads may be performed with a row address is provided and a word line is activated, and then data is read from CS0, CS1, CS2, and so forth. When a sequence of read operations is performed in this manner, if they are all associated with the same block of metadata, then the metadata block may be read once and stored in the metadata latches 123 and then as the data is read it is matched to associated the portion of that stored metadata by the metadata location decoder circuit 111. During write operations, the controller may write a sequence of data to sequential CS values along the row, and then provide a block of metadata to be written.

The device 100 includes refresh control circuits 116 each associated with a bank of the memory array 118. Each refresh control circuit 116 may determine when to perform a refresh operation on the associated bank. The refresh control circuit 116 provides a refresh address RXADD (along with one or more refresh signals, not shown in FIG. 1). The row decoder 108 performs a refresh operation on one or more word lines associated with RXADD. The refresh control circuit 116 may perform multiple types of refresh operation, which may determine how the address RXADD is generated, as well as other details such as how many word lines are associated with the address RXADD.

The ECC circuit 120 may detect and/or correct errors in the accessed data. As part of a write operation, the ECC circuit 120 may receive bits from the IO circuit 122 and generate parity bits based on those received bits. The received bits and parity bits are written to the memory array 118. During an example read operation, the ECC circuit 120 receives a set of bits and their associated parity bits from the array 118 and uses them to locate and/or correct errors. For example, in a single error correction (SEC) scheme, up to one bit of error may be located and detected. In a single error correction double error detection (SECDED) scheme, up to one bit of error may be corrected, but two errors may be detected (although the bits causing those errors are not individually located, so no correction can be made). The ECC circuit 120 may correct the information and then provide the corrected information (and/or a signal indicated detected errors) to the IO circuit 122. The parity bits may generally not be provided to the IO circuit 122.

The power supply terminals are supplied with power supply potentials VDD and VSS. The power supply potentials VDD and VSS are supplied to an internal voltage generator circuit 124. The internal voltage generator circuit 124 generates various internal potentials VARY, and the like based on the power supply potentials VDD and VSS supplied to the power supply terminals.

The power supply terminals are also supplied with power supply potentials VDDQ and VSSQ. The power supply potentials VDDQ and VSSQ are supplied to the input/output circuit 122. The power supply potentials VDDQ and VSSQ supplied to the power supply terminals may be the same potentials as the power supply potentials VDD and VSS supplied to the power supply terminals in an embodiment of the disclosure. The power supply potentials VDDQ and VSSQ supplied to the power supply terminals may be different potentials from the power supply potentials VDD and VSS supplied to the power supply terminals in another embodiment of the disclosure. The power supply potentials VDDQ and VSSQ supplied to the power supply terminals are used for the input/output circuit 122 so that power supply noise generated by the input/output circuit 122 does not propagate to the other circuit blocks.

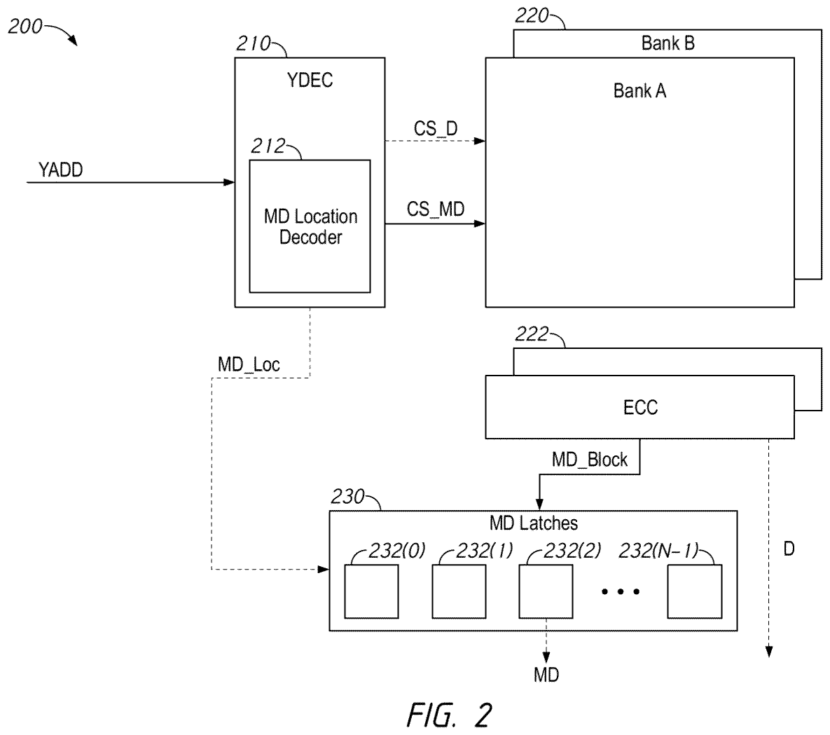

FIG. 2 is a block diagram of access circuits according to some embodiments of the present disclosure. The access circuits 200 may, in some embodiments, implement a portion of a memory device, such as the memory device 100 of FIG. 1. The access circuits 200 show components and signals relevant to performing read operations and locating a relevant portion of metadata. Certain components and signals (such as the row decoder, row address XADD and others) which may still be used as part of the described access operations, are not shown in FIG. 2.

The access circuits 200 include a column decoder 210 (e.g., 110 of FIG. 1) and a metadata location decoder circuit 212 (e.g., 111 of FIG. 1). The column decoder 210 provides column select signals CS to one or more memory banks 220 (e.g., 118 of FIG. 1) based on a column address YADD. The memory banks 220 provide data and/or metadata through one or more associated ECC circuits 222 (e.g., 120 of FIG. 1). The metadata is stored in metadata latches 230 (e.g., 123 of FIG. 1) and then a portion of the stored metadata is matched with read data D based on a metadata relative position signal MD_Loc provided by the metadata location decoder circuit 212.

In the example implementation of FIG. 2, access operations may be performed on two banks at a time 220, here labelled Bank A and Bank B. The two banks 220 may represent two banks selected by a bank address. The banks may act together during access operations. The two banks 220 may effectively act as if they were a single bank of twice the size of a single bank.

During an example read operation, the column decoder 210 receives a column address YADD. The column decoder 210 decodes the column address YADD into a column select signal. The value that the column address YADD is decoded into may represent a column select value associated with the data to be read, CS_D. In turn, the column decoder 210 may generate a metadata column select value CS_MD, which is associated with a block of metadata MD_Block which includes the metadata associated with the data to be read. The metadata CS value CS_MD may be generated based on the value of CS_D. For example if the value CS_D falls within a first range of values (e.g., 0≤CS_D<i−1) then CS_MD may have a first value CS_MD=X, if the value CS_D falls within a second range of values (e.g., i≤CS_D<j−1) then CS_MD may have a second value CS_MD=Y, if the value CS_D falls within a third range of values (j≤CS_D<k−1) then CS_MD may have a third value CS_MD=Z and so forth.

If the value of CS_MD is different than a previous value of CS_MD (e.g., CS_D is in a different range than the previous access operation), then the column decoder 210 may first perform an access pass based off of CS_MD to read out a block of metadata MD_Block associated with that value of CS_MD. The column decoder 210 provides CS_MD to the banks 220 and the metadata block and the parity associated with the metadata block is read out to the ECC circuits. For example, responsive to CS_MD, 256 bits of metadata and 16 bits of parity may be read out to the ECC circuits 222 (128 MD and 8 parity from each bank). The ECC circuits 222 may detect/correct errors in the metadata block MD_Block, and the metadata block is stored in the metadata latches 230. The metadata latches 230 include a number of different sets of latches 232. Each set of latches stores a portion of the metadata block MD_Block which is associated with a different block of data (e.g., a different CS_D value). The number of latch sets 232 may be based on how much metadata is associated with a block of data. For example, if the metadata block MD_Block is 256 and there are 16 bits of MD for each block of data, then there will be 16 sets of latches 232, each with 16 individual latch circuits. If there are 8 bits of MD for each block of data, then there will be 32 sets of latches 232, each with 8 individual latch circuits and so forth.

As a second access pass (or as the first access pass if CS_MD is the same value as the previous value of CS_MD), the data may be read. Signals which are provided as part of this data access pass are shown in dotted lines. The column decoder 210 provides the data CS value CS_D. Responsive to that, the banks 220 provide the data along with its associated parity. For example, 256 bits of data and 16 bits of parity may be read (128 data and 8 parity from each bank). The ECC circuits 222 detect/correct errors in the data and pass on the corrected data D.

The metadata location decoder circuit 212 generates a metadata relative position signal MD_Loc based on the data CS value CS_D and the range of values associated with the metadata CS value CS_MD. The metadata location decoder circuit 212 may subtract a minimum value of the range from the data CS_D value to get the value of relative position signal MD_Loc. For example, referring to the values above, if the value of CS_D is in the first range, then MD_Loc=CS_D−0, if the value of CS_D is in the second range then MD_Loc=CS_D−i, if the value of CS_D is in the third range then MD_Loc=CS_D−j and so forth.

The metadata location decoder circuit 212 provides the value of MD_Loc to the metadata latches 230. Each of the sets of latches 232 is indexed by a value of MD_Loc. So if MD_Loc has a first value, then the first set of latches 232(0) may be accessed. If MD_Loc has a second value, then the second set of latches 232(1) may be accessed. In this manner, the value of MD_Loc may represent a relative position of the metadata within the block of metadata. The set of latches indexed by the value of MD_Loc provides the metadata MD (e.g., along a metadata bus) which is provided, along with the data D.

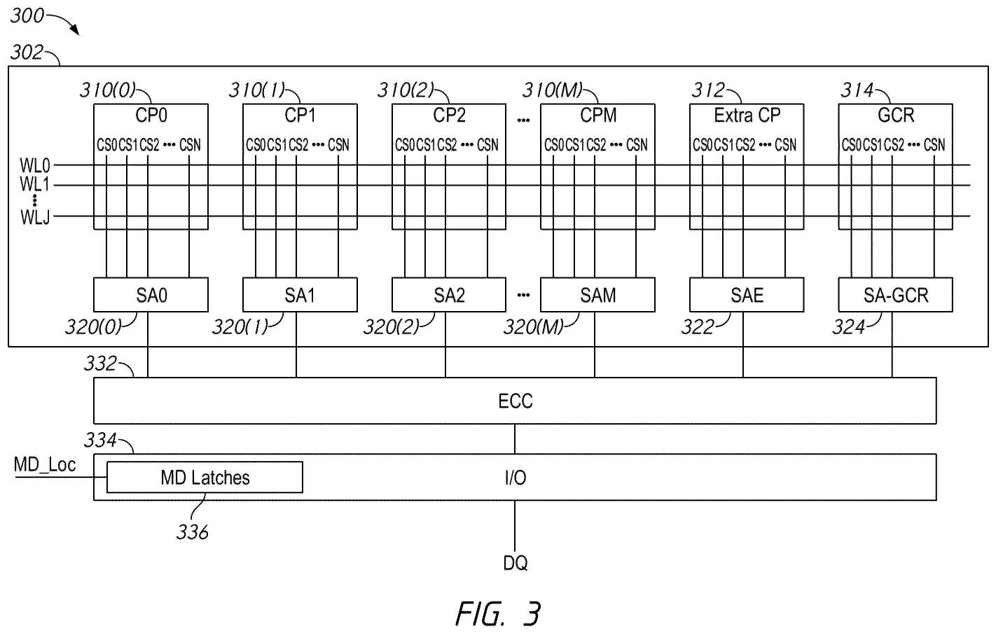

FIG. 3 is a block diagram of a memory device according to some embodiments of the present disclosure. The memory device 300 may, in some embodiments, represent a portion of the memory device 100 of FIGS. 1 and/or 200 of FIG. 2. The view of FIG. 3 shows a memory bank 302 (e.g., 118 of FIGS. 1 and/or 220 of FIG. 2) along with various other circuits used in the data path such as the ECC circuit 332 (e.g., 120 of FIGS. 1 and/or 222 of FIG. 2) and the IO circuit 334 (e.g., 122 of FIG. 1).

The view of FIG. 3 shows a single memory bank 302 and its associated ECC circuit 332. In some embodiments, such as LPDDR memory, multiple memory banks may be activated as part of a single access operation. This may operate in a manner similar to the singular bank 302 described in FIG. 3, however each of the components and signals, as well as the bits of data and metadata provided, may be repeated for both banks. The ECC circuit 332 and its operations may also be repeated.

The memory bank 302 is organized into a number of column planes 310-314. Each of the column planes 310-314 represents a portion of a memory bank. Each column plane 310-314 includes a number of memory cells at the intersection of word lines WL and bit lines. The word lines may be extend across multiple of the column planes 310-314. For example, when a row is activated, it may activate memory cells in each of the column planes 310-314. The bit lines may be specific to a single column plane.

The bit lines may be grouped together into sets which are activated in common by a value of a CS signal. For the sake of clarity, only a single vertical line is used to represent the bit lines of each column select set, however, there may be multiple bit lines accessed by that value of CS. For example, each vertical line may represent 8 individual bit lines, all accessed in common by a value of CS. As used herein, a ‘value’ of CS may refer to a decoded signal provided to sets of bit lines. So a first value may represent a first value of a multibit CS signal, or after decoding an active signal along a signal line associated with that value being active.

During an access operation a row decoder (e.g., 108 of FIG. 1) may decode the row address and activate a selected one of the word lines. The memory cells along the activated word line may be coupled to their respective bit lines. The sense amplifiers 320-324 coupled to those bit lines amplify the signal stored in the coupled memory cells onto the bit lines (or write an external bit onto the bit line). The CS signal determines which bit lines are coupled through LIOs and GIOs to the ECC circuit 332.

The memory band 302 includes a set of data column planes 310 as well as an extra column plane 312. The extra column plane 312 may be used to store additional information, such as error correction parity bits. In some embodiments, the memory bank 302 may also include an optional global column redundancy (GCR) column plane 314. In some embodiments, the data column planes 310 and extra column plane 312 may be generally similar to each other. In some embodiments, the GCR plane 314 may have fewer memory cells (e.g., fewer column select groups) than the data column planes 210. The GCR CP 314 includes a number of redundant columns which may be used as part of a repair operation. If a value of the CS signal is identified as including defective memory cells in one of the data column planes 310, then the memory may be remapped such that the data which would have been stored in that column plane for that value of CS is instead stored in the GCR CP 314.

In an example implementation, the memory bank 302 may include 16 data column planes 310(0)-310(15). Each of those data column planes 310 includes 64 sets of bit lines activated by a value of the column select signal, and each set of bit lines includes 8 bit lines. Accordingly, when a word line is opened responsive to a row address, and a column select signal is provided to each of the 16 column planes then 8 bits are accessed from each of the 16 column planes for a total of 128 bits. A column select signal is also provided to the extra column plane 312, which may be a same or different value than the one provided to the data column planes 310, for an additional 8 bits. If a repair has been performed, the GCR CP 314 may also be accessed and the value on a GCR LIO may be used while ignoring the LIO of the column plane it is replacing. Accordingly, during a typical access pass, an access operation may read or write 128 bits from the data column planes 310 (with 8 bits substituted from the GCR CP 314 if there has been a repair) along with 8 additional bits from the extra CP 312.

In an example write operation, the controller may provide 128 bits of information (per bank) either data or metadata depending on what is being written through the I/O circuit 334. The ECC circuit 332 generates 8 parity bits based on those 128 bits of information. The row decoder activates a word line based on the row address. The column decoder provides a value of the CS signal based on the provided column address. The column select sets are coupled to the sense amplifiers which write the 128 bits of information and the 8 bits of parity to the memory cells at the intersection of the selected bit lines and the active word line. The data or metadata may be written to the data column planes 310, and the parity may be written to the extra column plane 312.

In some example embodiments, such as LPDDR, the word line may remain active and the controller may perform consecutive operations on consecutive column select values. For example, the controller may provide a row address to activate a word line and then write to a first CS value, then a second (consecutive) CS value and so forth.

Because information is written in blocks of 128 bits (per bank), and the ratio of metadata to data is generally less than 1:1, the controller may perform a number of data write operations and then write the metadata. For example, if the ratio of metadata to data is 1:16 (e.g., 128 data bits to 8 metadata bits per bank) then the controller may perform up to 16 write operations along the word line before writing a block of metadata which includes the metadata for the written data. As described in more detail herein, certain CS values may be set aside for storing metadata. In some embodiments, during write operations, the controller may directly write the metadata by providing a column address associated with a metadata CS value. In some embodiments, the controller may indicate a metadata write operation and the range of data CS values it is associated with, and the column decoder may generate the CS value for writing the metadata.

Unlike write operations, where data and metadata may be written separately, during a read operation, data and its associated metadata are provided together. Accordingly, during a read operation, the controller may provide row and column addresses associated with a location of the data, and the memory may identify the metadata associated with the data so that the metadata can be provided along with the data.

In an example read operation, the memory may receive a row and column address. The row address may be decoded the row decoder activates a row decoder. The column address may be decoded into a data column select value CS_D which indicates the column select sets in the data column planes 310 where the data is stored. Based on the data column address CS_D the column decoder may also generate a metadata column select value CS_MD.

The metadata column select value CS_MD may be based on the memory's mapping of how the data and metadata are stored. For example, the value of CS_MD may be based on a range of values that CS_D falls within. In an example implementation, if each CS value accesses 128 bits (per bank), and there are 8 bits of metadata per data access (per data CS value), then each CS value used for metadata stores 16 data CS values worth of metadata. Since there are 64 possible CS values, then four CS values may be set aside for metadata, each associated with 16 CS values used for data. For example, the metadata may be stored in the last four CS values (CS60-CS63). Accordingly, when the CS_D is between 0 and 15, the CS_MD is CS60, when the CS_D is between 16 and 31 the CS_MD is CS61, and so forth. Other mappings may be used in other example embodiments, and more or fewer CS values may be set aside for metadata based on other ratios of data and metadata, other numbers of bit lines per CS set, and so forth.

After generating the CS_MD value, the column decoder may compare it to a previous value of CS_MD if the previous operation was a read operation. If there is not a match, then a two pass operation may be performed, first for the metadata and then for the data. If there is a match, then the metadata block including the associated metadata is already stored in the metadata latches 336 (e.g., 123 of FIGS. 1 and/or 230 of FIG. 2) and a single pass access operation can be performed on just the data.

In a two pass operation, as part of the first pass, the column decoder provides the metadata CS value CS_MD and the bit lines associated with CS_MD are coupled to the ECC circuit 332. Responsive to CS_MD, 128 bits of metadata (per bank) are read out from the data column planes 310, and 8 parity bits are read out from the extra column plane 312. The ECC circuit 332 detects/corrects errors in the metadata based on the parity. For example, the ECC circuit 332 may implement single error correction (SEC) where up to one bit of error may be located and corrected. The 128 bits of corrected metadata represent all or part of a block of metadata (e.g., MD_Block of FIG. 2) and are stored in the metadata latches 336. For example, if two banks are accessed per access operation, then the 128 of corrected metadata may represent half the metadata block and the other half may come from the other bank which was accessed.

In the one pass operation, or in the second pass of the two pass operation, the column decoder provides the data CS value CS_D, and the bit lines associated with CS_D are coupled to the ECC circuit 332. Responsive to CS_D 128 bits of data are read out from the data column planes 310 and 8 bits of parity are read out from the extra column plane 312. The ECC circuit 332 detects/corrects errors in the data and provides the corrected data to the IO circuit 334. In embodiments where multiple banks are accessed, the data may be combined with data provided from the other bank(s) accessed at the same time. A metadata location decoder circuit (e.g., 111 of FIGS. 1 and/or 212 of FIG. 2) provides a metadata location signal MD_Loc to the metadata latches, which indicates which of the metadata latches includes the metadata associated with this read operation. The selected portion of the metadata is provided with the read data to the DQ terminals.

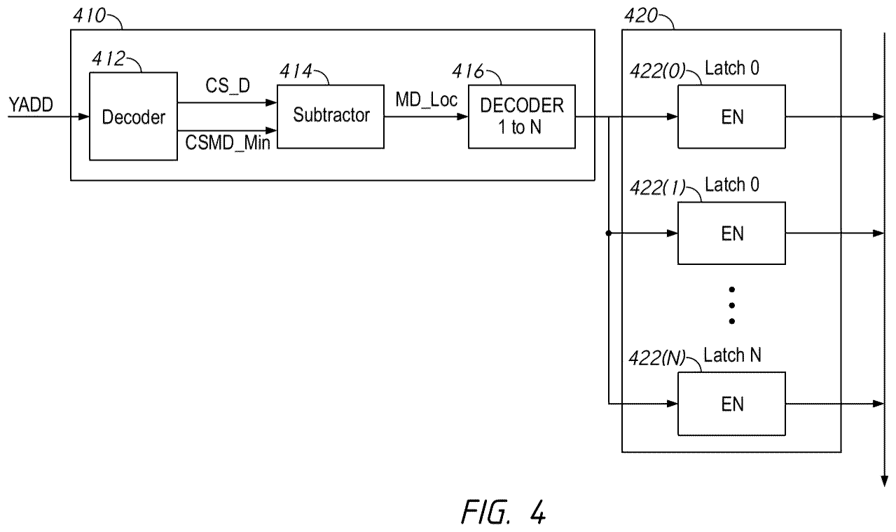

FIG. 4 is a block diagram of a metadata location decoder circuit according to some embodiments of the present disclosure. The metadata location decoder circuit 310 may, in some embodiments, implement the metadata location decoder circuit 111 of FIGS. 1 and/or 212 of FIG. 2. The metadata location decoder circuit 310 shows an arrangement of components which may be part of a column decoder such as 110 of FIGS. 1 and/or 210 of FIG. 2. Other arrangements of components may be used in other example embodiments. For example, certain components described as part of the metadata location decoder circuit 310 may be more general components of the column decoder which are shared with other functions of the decoder. Also shown in FIG. 4 is a set of metadata latches 420 which may implement the metadata latches 123 of FIG. 1, 230 of FIG. 2, and/or 336 of FIG. 3.

The metadata location decoder 410 includes a decoder circuit 412 which determines the data CS value CS_D and a minimum value CSMD_Min of the range of values associated with a metadata CS value that the CS_D value falls within. The metadata location decoder 410 also includes a subtractor circuit 414, which subtracts CSMD_Min from CS_D to generate a metadata location signal MD_Loc. A latch decoder circuit 416 decodes the metadata location signal MD_Loc to determine which set of latches 422 to the metadata latches 420 to couple to a metadata bus.

The decoder circuit 412 receives the row address and generates a data CS value CS_D based on the row address. Based on the mapping of data and metadata, the decoder 412 also generates a metadata CS value based on the range of values that CS_D falls within. For example, referring back to the example implementation discussed with respect to FIG. 3, if the value of CS_D is between 0 and 15, the CS_MD may have a first value (e.g., CS60), if the value of CS_D is between 16 and 31 then CS_MD may have a second value (e.g., CS61), if the value of CS_D is between 32 and 47 then CS_MD may have a third value (e.g., CS62) and if the value of CS_D is between 48 and 59 (since CS60-CS63 are used for MD) then CS_MD may have a fourth value (e.g., CS63). Based on the range used to determine CS_MD, the decoder circuit 412 may also provide a minimum value CSMD_Min which represents a minimum value of the range of values used to determine CS_MD that the value of CS_D fell within. For example, using the above example implementation, if CS_D is between 0 and 15, then CSMD_Min would be 0. If CS_D is between 16 and 31, then CSMD_Min would be 16 and so forth.

The subtractor circuit 414 determines a value of the MD location signal MD_Loc based on the data CS value CS_D and the minimum value CSMD_Min. The value of MD_Loc may be determined based on equation 1, below:

$$MD\_Loc = CS\_D - CSMD\_Min \qquad Eqn . 1$$

In this manner, the value of MD_Loc may represent a relative position of the value of CS_D within the range of values which was is associated with the value of CS_MD which was used.

The latch decoder circuit 416 decodes the value of MD_Loc into a signal which activates one of the sets of latches 422 of the metadata latches 420. For example, there may be N+1 sets of latches 422(0) to 422(N) each of which store K bits of metadata (e.g., each set may include latches 0 to K−1). The N+1 sets of latches may represent N+1 possible values of MD_Loc or how many different values of CS_D are in a range. Based on the decoded value of MD_Loc, one of the sets of latches is activated and provides its K bits to the a metadata bus to be read out to the DQ terminals.

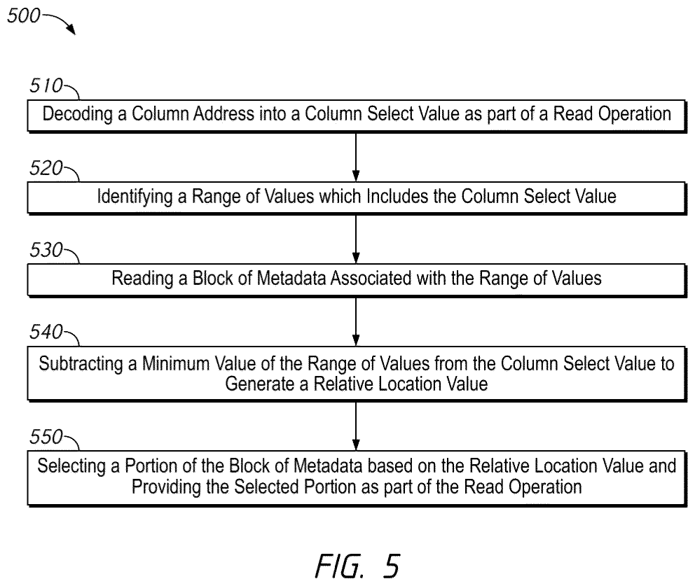

FIG. 5 is a flow chart of a method according to some embodiments of the present disclosure. The method 500 may, in some embodiments, be implemented by one or more of the apparatuses or systems described herein. For example, the method 500 may be performed by the memory devices 100 of FIG. 1, 200 of FIG. 2, and/or 300 of FIG. 3. In particular, the method 500 may be performed by a metadata location decoder circuit such as 111 of FIG. 1, 212 of FIGS. 2 and/or 410 of FIG. 4.

The method 500 begins with block 510, which describes decoding a column address into a column select value (e.g., a data column select value CS_D) as part of a read operation. Block 510 may be followed by block 520, which describes identifying a range of values which includes the column select value. For example, the method 500 may include determining if the column select value falls within a first range, a second range, a third range, and so forth. The method 500 may include generating a second column select value (e.g., a metadata column select value CS_MD) based on the identified range. The method 500 may include comparing the second column select value to a previous second column select value from a previous read operation. If there is not a match, the method may proceed to block 530. If there is a match, the method may include skipping block 530 and proceeding to block 540 instead.

Block 530 describes reading a block of metadata associated with the range of values. The block of metadata may include a number of portions, each of which is associated with a different block of data which could be read from a different CS value within the range of CS values associated with that block of metadata. The method may include providing the second CS value and reading the block of metadata based on the second CS value. The method may include reading a plurality of parity bits along with the block of metadata and correcting/detecting errors in the block of metadata based on the plurality of parity bits with an error correction circuit (e.g., 120 of FIG. 1, 222 of FIG. 2, and/or 332 of FIG. 3).

The method 500 may include storing the block of metadata in a metadata latch circuit, such as 123 of FIG. 1, 222 of FIG. 2, 336 of FIGS. 3, and/or 420 of FIG. 4. The method 500 may include storing different portions of the block of metadata in different sets of latches of the metadata latch circuit.

The method 500 may include reading a plurality of bits of data based on the column select value. Reading the plurality of data bits may be a separate access pass from reading the metadata block and may come after reading the metadata block. If reading the metadata block is skipped, the method may still include reading the plurality of data bits. The method may include reading a second plurality of parity bits associated with the plurality of data bits and detecting/correcting errors in the plurality of data bits based on the second plurality of parity bits with the error correction circuit.

Block 530 may generally be followed by block 540, which describes subtracting a minimum value of the range of values from the column select value to generate a relative location value (e.g., MD_Loc). For example, the subtracting may be done by a subtractor circuit (e.g., 414 of FIG. 4) of a MD location decoder circuit (e.g., 111 of FIG. 1, 212 of FIG. 2, and/or 410 of FIG. 4).

Block 540 may generally be followed by block 550, which describes selecting a portion of the block of metadata based on the relative location value and providing the selected portion as part of the read operation. For example, the method may include selecting one of the sets of latches of the metadata latches based on the relative location value. The method may include providing the selected portion of the block of metadata along with the plurality of data bits to data terminals.

Of course, it is to be appreciated that any one of the examples, embodiments or processes described herein may be combined with one or more other examples, embodiments and/or processes or be separated and/or performed amongst separate devices or device portions in accordance with the present systems, devices and methods.

Finally, the above discussion is intended to be merely illustrative of the present system and should not be construed as limiting the appended claims to any particular embodiment or group of embodiments. Thus, while the present system has been described in particular detail with reference to exemplary embodiments, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

What is claimed is:

1. An apparatus comprising:
a memory array;
a column decoder configured to decode a column address into a value of a column select signal and read a block of metadata bits from the memory array based on a range of values that the value of the column select signal falls within;
a metadata location decoder circuit configured to identify a relative location of the value of the column select signal within the range of values and configured to select a portion of the block of metadata bits based on the relative location.

2. The apparatus of claim 1, wherein the metadata location decoder circuit includes a subtractor circuit configured to subtract a minimum value of the range of values from the value of the column select signal to generate a relative location signal.

3. The apparatus of claim 1, wherein the column decoder is further configured to read a plurality of data bits from the memory array based on the column select signal value, wherein the selected portion of the block of metadata bits is associated with the plurality of data bits.

4. The apparatus of claim 1, further comprising a metadata latch circuit comprising a plurality of sets of latches, wherein one of the plurality of sets of latches is selected based on the relative location value.

5. The apparatus of claim 1, wherein the column decoder is configured to generate second column select value based on the range of values, read the block of metadata from the memory array based on the second column select value.

6. The apparatus of claim 5, wherein the column decoder is configured to compare the second column select value to a previous column select value and not read the plurality of metadata if they match.

7. The apparatus of claim 1, wherein the memory array comprises a first and a second bank, and wherein the block of metadata bits is read from the first and the second bank.

8. An apparatus comprising:
a memory array;
a decoder circuit configured to decode a column address into a first column select value, identify a range of values that the first column select value falls within, generate a second column select value based on the identified range, and read a block of metadata from the memory array based on the second column select value; and
a subtractor circuit configured to subtract a minimum value of the identified range of values from the first column select value to generate a relative location value, wherein a portion of the block of metadata is selected based on the relative location value.

9. The apparatus of claim 8, further comprising a metadata latch circuit comprising a plurality of sets of latches configured to store the block of metadata.

10. The apparatus of claim 9, further comprising a second decoder circuit configured to select one of the plurality of sets of latches based on the relative location value.

11. The apparatus of claim 8, wherein the decoder circuit is configured to read a plurality of data bits from the memory array based on the first column select value.

12. The apparatus of claim 11, wherein the metadata block is 256 bits of metadata, the portion of the block of metadata is 16 bits, and the plurality of data bits is 256 bits of data.

13. The apparatus of claim 8, wherein the decoder circuit is further configured to read a plurality of parity bits based on the second column select value, the apparatus further comprising an error correction code (ECC) circuit configured to receive block of metadata and the plurality of parity bits and correct errors in the block of metadata based on the plurality of parity bits.

14. A method comprising:
decoding a column address into a column select value as part of a read operation;
identifying a range of values which includes the column select value;
reading a block of metadata associated with the range of values;
subtracting a minimum value of the range of values from the column select value to generate a relative location value;
selecting a portion of the block of metadata based on the relative location value and providing the selected portion as part of the read operation.

15. The method of claim 14, further comprising:
generating a second column select value based on the range of values; and
reading the block of metadata based on the second column select value.

16. The method of claim 15, further comprising:
comparing the second column select value to a previous second column select value from a previous read operation; and
skipping reading the block of metadata if the second column select value matches the previous second column select value.

17. The method of claim 14, further comprising:
reading a plurality of bits of data based on the column select value; and
providing the plurality of bits of data with the selected portion of the block of metadata as part of the read operation.

18. The method of claim 14, further comprising:
storing portions of the block of metadata in respective sets of latches of a metadata latch circuits; and
selecting one of the sets of latches based on the relative location value.

19. The method of claim 14, further comprising reading the block of metadata from a first bank and a second bank of a memory array.

20. The method of claim 14, further comprising:
reading a plurality of parity bits associated with the block of metadata; and
detecting or correcting errors in the block of metadata based on the plurality of parity bits.
